(19) United States
(12) Patent Application Publication
(10) Pub. No.: US 2025/0294735 A1
(43) Pub. Date: Sep. 18, 2025

(54) NON-VOLATILE MEMORY DEVICE AND MANUFACTURING METHOD OF THE SAME

(71) Applicant: Powerchip Semiconductor Manufacturing Corporation, Hsinchu (TW)

(72) Inventor: Wen-Yueh Chang, Hsinchu City (TW)

(73) Assignee: Powerchip Semiconductor Manufacturing Corporation, Hsinchu (TW)

(21) Appl. No.: 18/655,344

(22) Filed: May 6, 2024

(30) Foreign Application Priority Data
Mar. 13, 2024 (TW) 113109091

(51) Int. Cl. H10B 41/30; H01L 29/423; H10B 41/10

(52) U.S. Cl. CPC H10B 41/30; H10B 41/10; H10D 30/6894

(57) ABSTRACT

A non-volatile memory device includes a substrate, a source line in the substrate, a semiconductor epitaxial layer on the substrate, a device isolation structure, a trench, a floating gate, a control gate, a tunnel oxide layer, an inter-gate dielectric layer, a drain region, and a bit line. The device isolation structure is disposed in the semiconductor epitaxial layer and extends in a first direction. The trench is formed in the semiconductor epitaxial layer and crosses the device isolation structure in a second direction. The floating gate, the control gate, the tunnel oxide layer, and the inter-gate dielectric layer are in the trench, and the control gate extends in the second direction. The drain region is formed in the semiconductor epitaxial layer on both sides of the control gate. The bit line extends on the semiconductor epitaxial layer in the first direction and is electrically connected to the drain region.

### CROSS-REFERENCE TO RELATED APPLICATION

This application claims the priority benefit of Taiwan application serial no. 113109091, filed on Mar. 13, 2024. The entirety of the above-mentioned patent application is hereby incorporated by reference herein and made a part of specification.

### BACKGROUND

### Technical Field

The disclosure relates to a semiconductor memory technology, and in particular, relates to a non-volatile memory device and a manufacturing method of the same.

### Description of Related Art

Non-volatile memories provide the advantage that stored data does not disappear after a power outage, so many electrical products are required to be equipped with this kind of memories to maintain normal operation when the electrical products are turned on. In a non-volatile memory that uses the floating gate to store charges, the memory cell generally includes a tunnel oxide layer, a floating gate, an inter-gate dielectric layer, and a control gate that are sequentially disposed on a substrate.

The above-mentioned non-volatile memory generally adopts the approach of hot electron injection for high-speed programming. However, larger device size is required, so as to prevent the drain-to-source punch through effect from occurring. Further, there are interference problems from the bit lines (through the drain), the word lines (through the control gate), and block erase (from the well region). In addition, the approach of hot electron injection may easily cause damage to the tunnel oxide layer, and the durability (write/erase cycle) of the non-volatile memory may thus be affected.

### SUMMARY

The disclosure provides a non-volatile memory device capable of providing reduced device size and writing or erasing electrons in a floating gate FG by FN tunneling through a source line SL, so high durability and low operating current suitable for multi-bit programming are provided.

The disclosure further provides a manufacturing method of a non-volatile memory device capable of manufacturing the above non-volatile memory device.

The disclosure provides a non-volatile memory device including a substrate, a source line formed in the substrate, a semiconductor epitaxial layer formed on the substrate, a device isolation structure, a trench, a floating gate, a control gate, a tunnel oxide layer, an inter-gate dielectric layer, a drain region, and a bit line. The device isolation structure is formed in the semiconductor epitaxial layer and extends in a first direction. The trench is formed in the semiconductor epitaxial layer and crosses the device isolation structure in a second direction. A bottom portion of the trench exposes the source line. The floating gate is disposed in the trench. The tunnel oxide layer is disposed between the floating gate and the source line. The control gate is disposed above the floating gate and extends in the second direction. The inter-gate dielectric layer is disposed between the floating gate and the control gate. A plurality of drain regions are formed in the semiconductor epitaxial layer on both sides of the control gate. The bit line extends on the semiconductor epitaxial layer in the first direction and is electrically connected to the drain region.

In an embodiment of the disclosure, the source line extends in the first direction and overlaps the bit line.

In an embodiment of the disclosure, the source line extends in the second direction and overlaps the control gate.

In an embodiment of the disclosure, a top portion of the control gate is lower than a top portion of the trench.

In an embodiment of the disclosure, the non-volatile memory device further includes a dielectric layer between the control gate and the bit line, and the dielectric layer fills the trench.

In an embodiment of the disclosure, the trench has a first depth at a location where the floating gate is formed, the trench has a second depth at a location where the trench intersects the device isolation structure, and the first depth is greater than the second depth.

In an embodiment of the disclosure, the bit line is in direct contact with the drain region.

In an embodiment of the disclosure, the tunnel oxide layer further extends between the floating gate and the semiconductor epitaxial layer.

In an embodiment of the disclosure, the inter-gate dielectric layer further extends between the control gate and the drain region.

In an embodiment of the disclosure, the inter-gate dielectric layer includes a high dielectric constant (high-k) layer or an ONO layer.

The disclosure further provides a manufacturing method of a non-volatile memory device, and the method includes the following steps. A source line is formed in a substrate, and a semiconductor epitaxial layer is formed on the substrate. A plurality of device isolation structures are formed in the semiconductor epitaxial layer in a first direction, and a trench is formed in the semiconductor epitaxial layer. The trench crosses the device isolation structures in a second direction, and a bottom portion of the trench exposes the source line. A tunnel oxide layer is formed in the trench, a floating gate is formed on the bottom portion of the trench, a portion of the tunnel oxide layer is exposed, and the exposed tunnel oxide layer is then removed. An inter-gate dielectric layer is formed on side walls of the trench and the floating gate, a control gate is formed in the trench on the floating gate, and a portion of the inter-gate dielectric layer is exposed. A plurality of drain regions are formed in the semiconductor epitaxial layer on both sides of the control gate. A bit line extending in the first direction is formed on the semiconductor epitaxial layer, and the bit line is electrically connected to the plurality of drain regions.

In another embodiment of the disclosure, the step of forming the source line in the substrate further includes the following step. The source line extending in the first direction is formed.

In another embodiment of the disclosure, the step of forming the source line in the substrate further includes the following step. The source line extending in the second direction is formed.

In another embodiment of the disclosure, after the control gate is formed, the method further includes the following step. The trench is filled with a dielectric layer.

In another embodiment of the disclosure, the step of forming the trench in the semiconductor epitaxial layer further includes the following step. Dry etching is performed on the semiconductor epitaxial layer and the device isolation structures. Through an etching selection ratio between the semiconductor epitaxial layer and the device isolation structures, the trench is allowed to have a first depth between the device isolation structures and a second depth at a location where the trench intersects the device isolation structures. The first depth is greater than the second depth.

In another embodiment of the disclosure, the step of forming the control gate includes the following step. A conductor material filling the trench is formed on the semiconductor epitaxial layer first, the conductor material outside the trench is removed through a planarization process, and a portion of the conductor material is then etched, so that a top portion of the control gate is lower than a top portion of the trench.

In another embodiment of the disclosure, the bit line is in direct contact with the drain regions.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a top view of a non-volatile memory device according to a first embodiment of the disclosure.

FIG. 1B is a cross-sectional schematic view of the non-volatile memory device of FIG. 1A taken along a line segment I-I′.

FIG. 1C is a cross-sectional schematic view of the non-volatile memory device of FIG. 1A taken along a line segment II-II′.

FIG. 1D is a cross-sectional schematic view of the non-volatile memory device of FIG. 1A taken along a line segment III-III′.

FIG. 2A is a top view of a non-volatile memory device according to a second embodiment of the disclosure.

FIG. 2B is a cross-sectional schematic view of the non-volatile memory device of FIG. 2A taken along a line segment I-I′.

FIG. 2C is a cross-sectional schematic view of the non-volatile memory device of FIG. 2A taken along a line segment II-II′.

FIG. 2D is a cross-sectional schematic view of the non-volatile memory device of FIG. 2A taken along a line segment III-III′.

FIG. 3 is an equivalent circuit diagram of a non-volatile memory device according to the above embodiments of the disclosure.

FIG. 4A to FIG. 4G are cross-sectional schematic views of a manufacturing process of a non-volatile memory device corresponding to the line segment I-I′ in FIG. 1A according to a third embodiment of the disclosure.

FIG. 5A to FIG. 5E are cross-sectional schematic views of the manufacturing process of the non-volatile memory device corresponding to the line segment II-II′ in FIG. 1A according to the third embodiment.

FIG. 6A to FIG. 6D are cross-sectional schematic views of the manufacturing process of the non-volatile memory device corresponding to the line segment III-III′ in FIG. 1A according to the third embodiment.

### DESCRIPTION OF THE EMBODIMENTS

The accompanying drawings are included together with the detailed description provided below to provide a further understanding of the disclosure. Note that in order to make the drawings to be more comprehensible to readers and for the sake of clarity of the drawings, only part of the electronic device is depicted in the drawings of the disclosure, and specific devices in the drawings are not depicted according to actual scales. Moreover, the quantity and the size of each device in the drawings are only schematic and exemplary and are not intended to limit the scope of protection provided in the disclosure. Further, directional terms such as “up” and “down” mentioned in the specification are only used to refer to the direction of the drawings and are not used to limit the disclosure. In the following specification and claims, “include” or similar words shall be interpreted to mean “including but not limited to . . . ”.

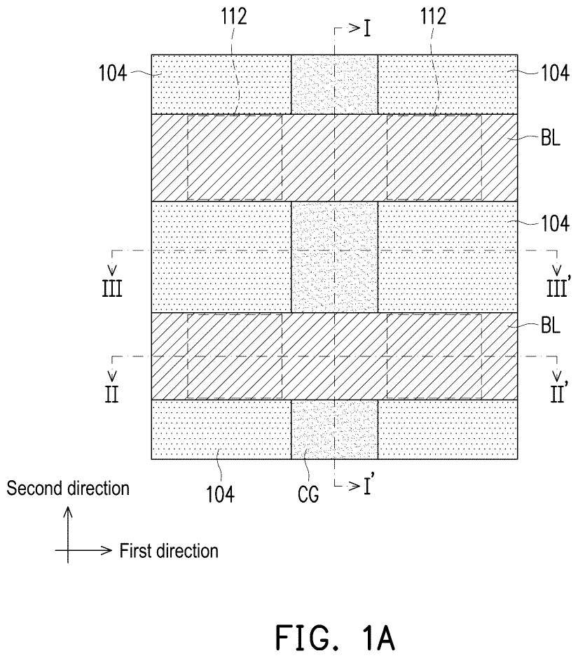

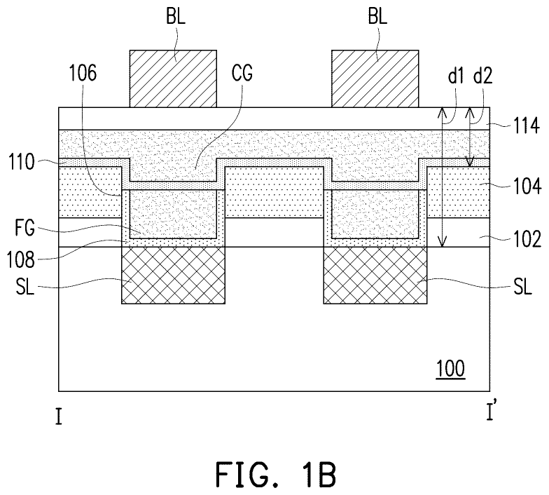

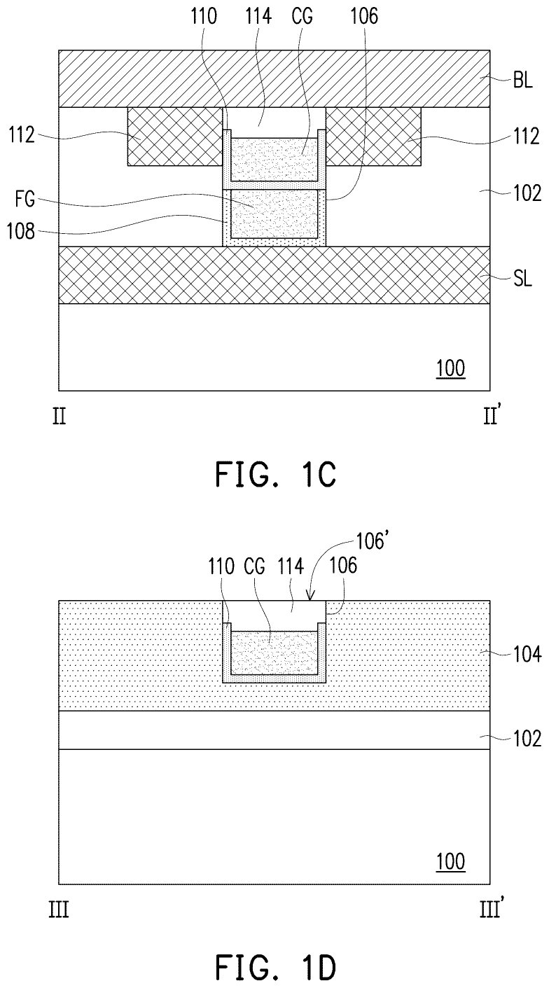

FIG. 1A is a top view of a non-volatile memory device according to a first embodiment of the disclosure. FIG. 1B is a cross-sectional schematic view of the non-volatile memory device of FIG. 1A taken along a line segment I-I′. FIG. 1C is a cross-sectional schematic view of the non-volatile memory device of FIG. 1A taken along a line segment II-II′. FIG. 1D is a cross-sectional schematic view of the non-volatile memory device of FIG. 1A taken along a line segment III-III′.

With reference to FIG. 1A to FIG. 1D together, in the first embodiment, a non-volatile memory device includes a substrate 100, a source line SL formed in the substrate 100, a semiconductor epitaxial layer 102 formed on the substrate 100, a device isolation structure 104, a trench 106, a floating gate FG, a control gate CG, a tunnel oxide layer 108, an inter-gate dielectric layer 110, a drain region 112, and a bit line BL. In an embodiment, the substrate 100 is a silicon substrate, and the semiconductor epitaxial layer 102 is a silicon epitaxial layer.

With reference to FIG. 1A, FIG. 1B, and FIG. 1D together, the device isolation structure 104 is formed in the semiconductor epitaxial layer 102 and extends in a first direction. The trench 106 is formed in the semiconductor epitaxial layer 102 and crosses the device isolation structure 104 in a second direction. A bottom portion of the trench 106 exposes the source line SL. In the first embodiment, the source line SL extends in the first direction and overlaps the bit line BL. That is, from a top view, positions of the source line SL and the bit line BL overlap, so the source line SL and the bit line BL both extend in the first direction. Besides, the trench 106 itself has varying depths. The trench 106 has a first depth d1 at a location where the floating gate FG is formed and has a second depth d2 at a location where it intersects the device isolation structure 104, and the first depth d1 is greater than the second depth d2. Such a structural feature may be achieved through an etching selection ratio between the device isolation structure 104 and the semiconductor epitaxial layer 102. For instance, an etchant (or gas) exhibiting a high etching rate for the semiconductor epitaxial layer 102 but a low etching rate for the device isolation structure 104 is used in the process of forming the trench 106. Therefore, as shown in FIG. 1B, the portion without the device isolation structure 104 is etched until the source line SL is exposed from the bottom portion of the trench 106. As for the portion where the device isolation structure 104 is present, the etching rate becomes lower, so that part of the device isolation structure 104 still exists at the bottom portion of the trench 106 there.

With reference to FIG. 1A, FIG. 1B, and FIG. 1C, the floating gate FG is located in the trench 106. The tunnel oxide layer 108 is located between the floating gate FG and the source line SL (as shown in FIG. 1B), and the tunnel oxide layer 108 further extends between the floating gate FG and the semiconductor epitaxial layer 102 (as shown in FIG. 1C). The control gate CG is disposed above the floating gate FG and extends in the second direction (as shown in FIG. 1A). The inter-gate dielectric layer 110 is disposed between the floating gate FG and the control gate CG. The inter-gate dielectric layer 110 is, for example, a high dielectric constant (high-k) layer or an ONO layer, which can increase the capacitive coupling between the floating gate FG and the control gate CG on the semiconductor epitaxial layer 102. In this embodiment, a top portion of the control gate CG may be lower than a top portion 106′ of the trench 106, so that control gate CG and the bit line BL thereon are electrically isolated by filling the dielectric layer 114 in the trench 106 between the control gate CG and the bit line BL. The dielectric layer 114 is, for example, an oxide layer. Nevertheless, the disclosure is not construed as limited thereto. In another embodiment, the top portion of the control gate CG may be flush with the top portion 106′ of the trench 106, and the control gate CG and the bit line BL are separated by an insulating layer (not shown) formed entirely on the semiconductor epitaxial layer 102.

With reference to FIG. 1A and FIG. 1C together, the drain region 112 is formed in the semiconductor epitaxial layer 102 on both sides of the control gate CG. Therefore, the drain region 112 is surrounded by the control gate CG and the device isolation structure 104 surrounding it. The bit line BL extends on the semiconductor epitaxial layer 102 in the first direction and is electrically connected to the drain region 112. In another embodiment, another inner dielectric layer (not shown) may be provided above the semiconductor epitaxial layer 102 to separate the bit line BL and the drain region 112, and the bit line BL and the drain region 112 may be connected through a conductive plug such as a via window in the inner dielectric layer. From the perspective of reducing resistance, the bit line BL is preferably in direct contact with the drain region 112. In FIG. 1C, the inter-gate dielectric layer 110 may further extend between the control gate CG and the drain region 112.

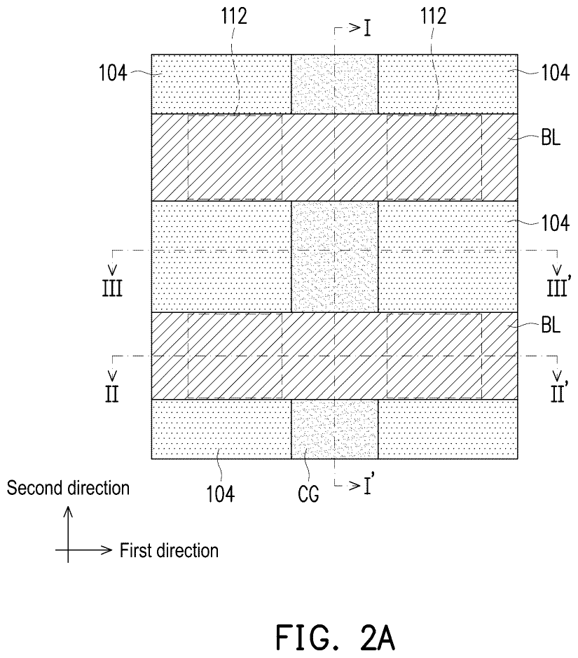

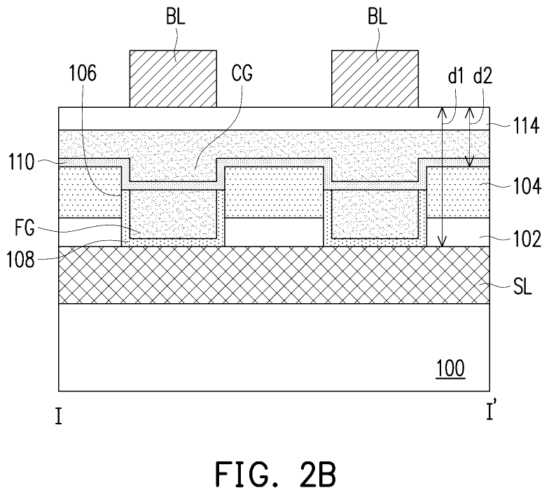

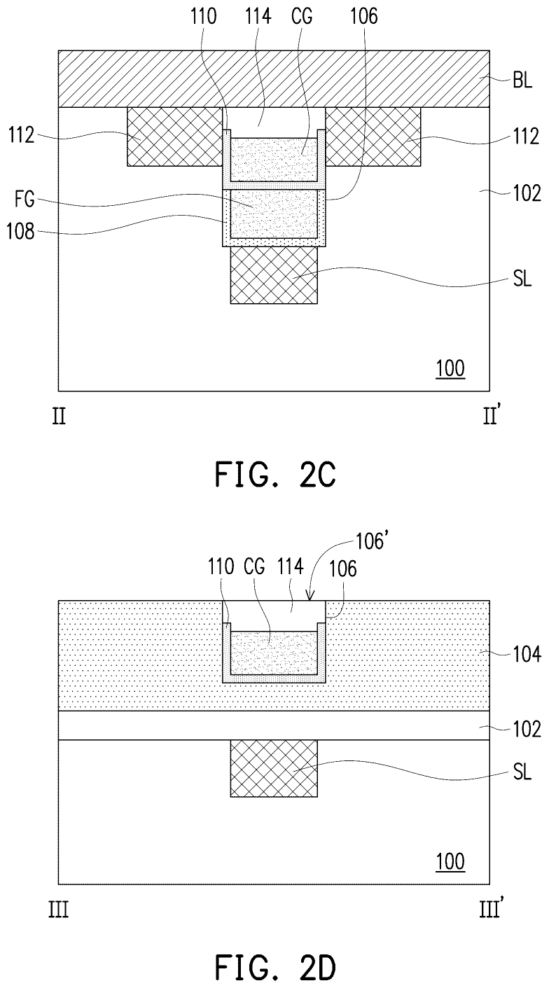

FIG. 2A is a top view of a non-volatile memory device according to a second embodiment of the disclosure. FIG. 2B is a cross-sectional schematic view of the non-volatile memory device of FIG. 2A taken along a line segment I-I′. FIG. 2C is a cross-sectional schematic view of the non-volatile memory device of FIG. 2A taken along a line segment II-II′. FIG. 2D is a cross-sectional schematic view of the non-volatile memory device of FIG. 2A taken along a line segment III-III′. In FIG. 2A to FIG. 2D, the same reference numerals as those in the first embodiment are used to represent the same or similar parts and components, and the relevant content of the same or similar parts and components may also be referred to the content of the first embodiment, so description thereof is not repeated.

With reference to FIG. 2A to FIG. 2D together, the difference between this embodiment and the first embodiment is that the source line SL extends in the second direction and overlaps the control gate CG. That is, from a top view, the positions of the source line SL and the control gate CG overlap, so the source line SL and the control gate CG both extend in the second direction. Therefore, the non-volatile memory device of this embodiment can easily program a plurality of bits along the same word line (i.e., the control gate CG). In contrast, a single bit may be easily programmed in the first embodiment.

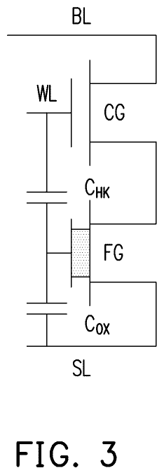

FIG. 3 is an equivalent circuit diagram of a non-volatile memory device according to the above embodiments of the disclosure. The vertically distributed floating gate FG and control gate CG are shown, so that the overall circuit is similar to the previous planar non-volatile memory, but device sizes can be significantly reduced. Further, the control gate CG (acting as a word line) and the floating gate FG in both the first and second embodiments are connected in series as bit selection transistors. Therefore, electrons in the floating gate FG can be written or erased by FN tunneling through the source line SL, so high durability and low operating current suitable for multi-bit programming are provided. Further, since channel lengths are all in a vertical direction (at the side walls of trench 106), a cell size on a horizontal surface can be reduced.

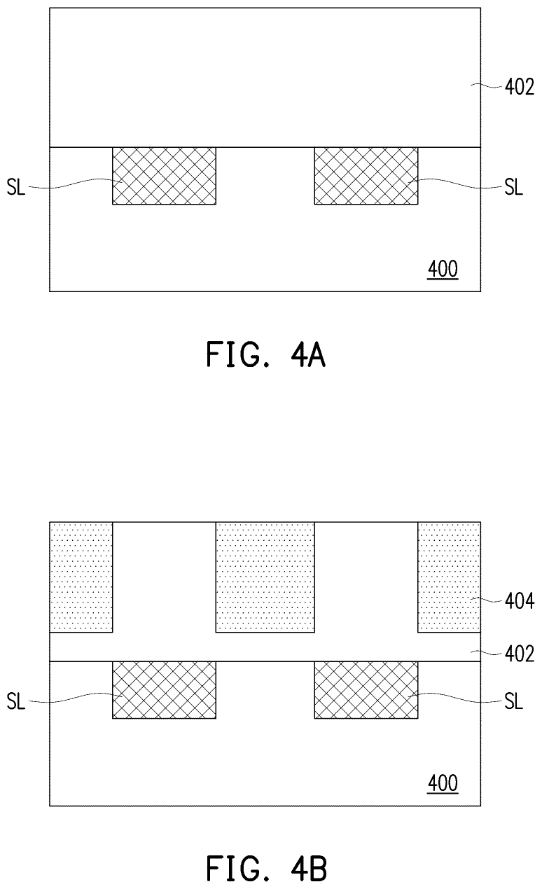

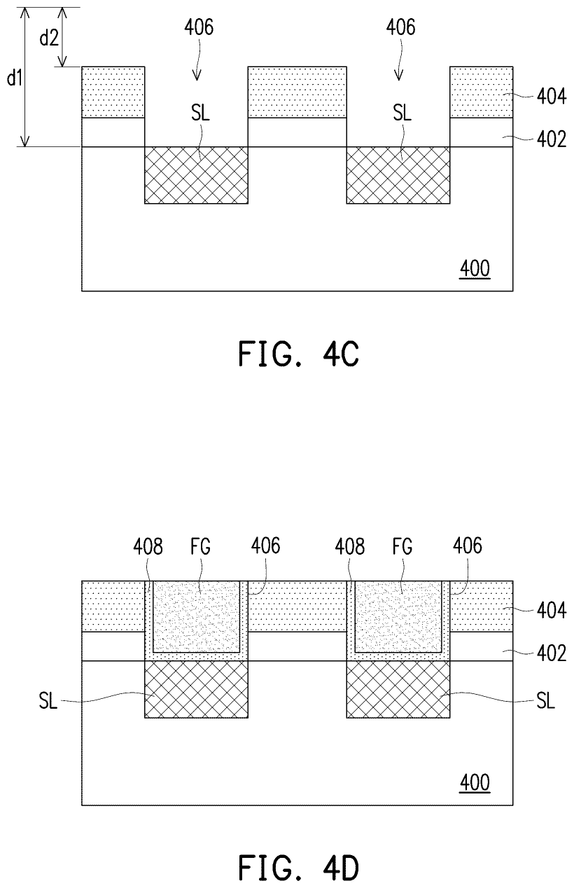

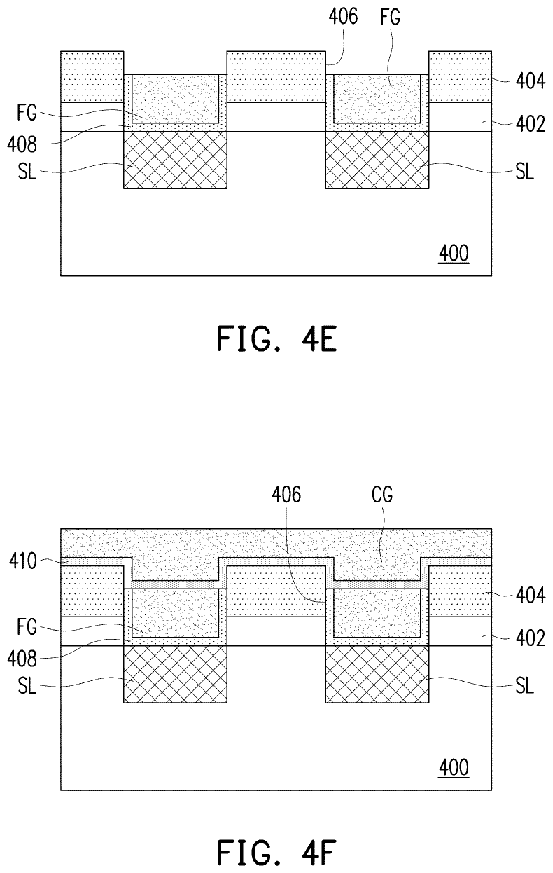

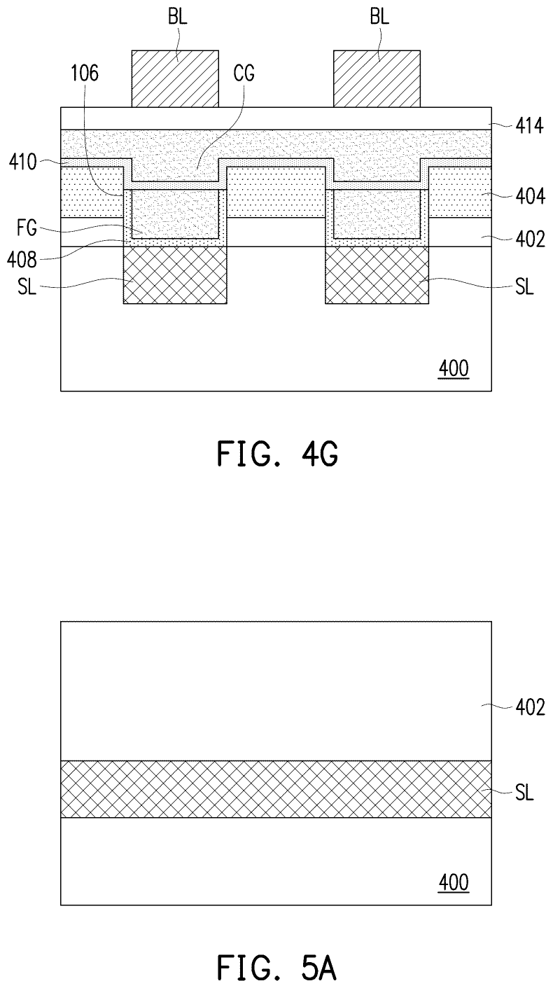

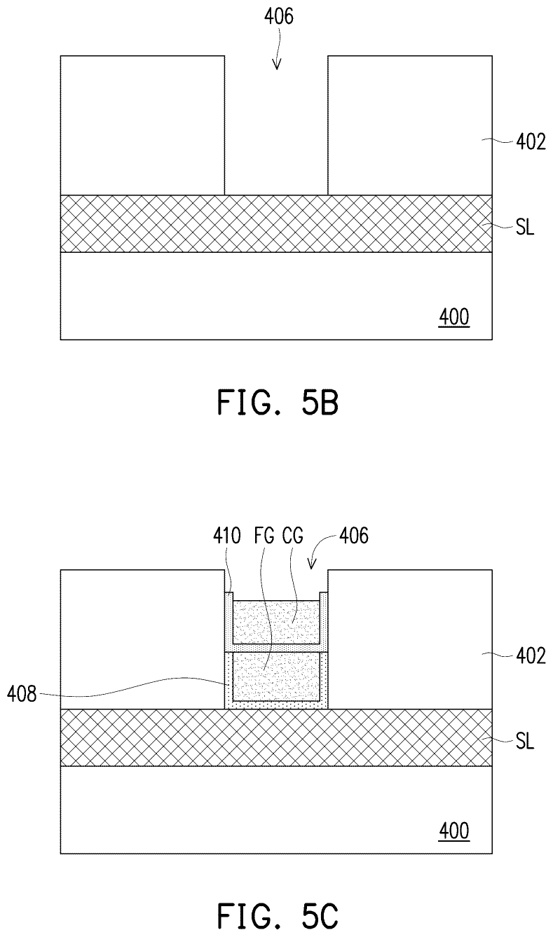

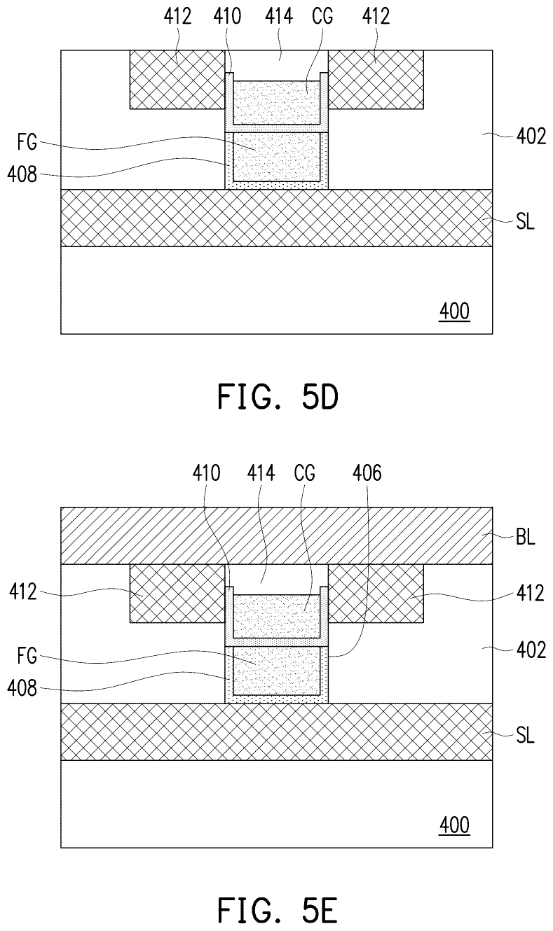

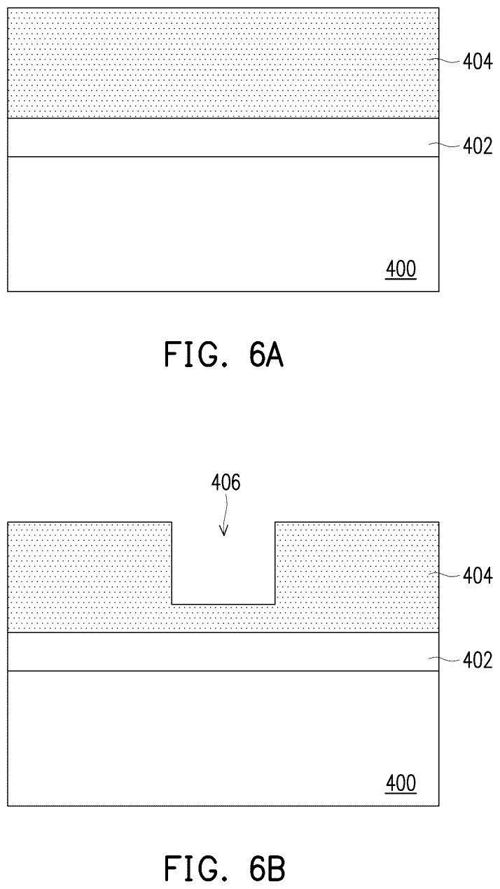

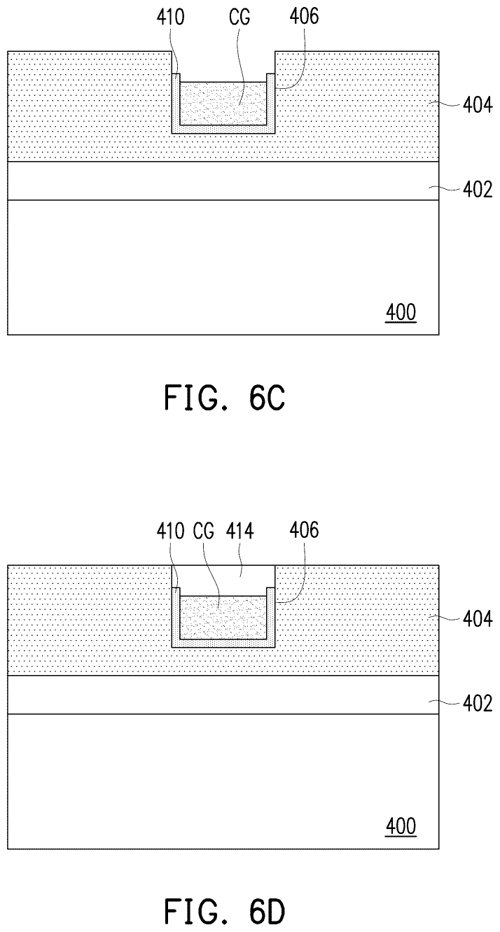

FIG. 4A to FIG. 4G are cross-sectional schematic views of a manufacturing process of a non-volatile memory device corresponding to the line segment I-I′ in FIG. 1A according to a third embodiment of the disclosure. FIG. 5A to FIG. 5E are cross-sectional schematic views of the manufacturing process of the non-volatile memory device corresponding to the line segment II-II′ in FIG. 1A according to the third embodiment. FIG. 6A to FIG. 6D are cross-sectional schematic views of the manufacturing process of the non-volatile memory device corresponding to the line segment III-III′ in FIG. 1A according to the third embodiment.

With reference to FIG. 4A and FIG. 5A together, source lines SL are formed in a substrate 400, and a semiconductor epitaxial layer 402 is formed on the substrate 400. The source lines SL are formed in the first direction in the substrate 400 through a photolithography process to form the source lines SL, for example, but it is not limited to, where the source lines SL are, for example, N+ doped regions. In another embodiment, the step of forming the source lines SL includes forming the source lines SL extending in the second direction different from (or perpendicular to) the first direction, so that the final formed device is shown as shown in FIG. 2B.

Next, with reference to FIG. 4B and FIG. 6A together, a plurality of device isolation structures 404 extending in the first direction are formed in the semiconductor epitaxial layer 402, so that the device isolation structures 404 and the source lines SL are distributed in an alternating manner when viewed from a top view. In an embodiment, a thickness of the semiconductor epitaxial layer 402 may be greater than a thickness of each of the device isolation structures 404, so the device isolation structures 404 do not contact the source lines SL. First, a plurality of channels extending in the first direction are formed in the semiconductor epitaxial layer 402, the channels are filled with an insulating material, and excess insulating material above the semiconductor epitaxial layer 402 is removed through a planarization process (e.g., CMP) to form the device isolation structures 404, for example, but it is not limited thereto.

Next, with reference to FIG. 4C, FIG. 5B, and FIG. 6B together, a trench 406 is formed in the semiconductor epitaxial layer 402, and the trench 406 crosses the device isolation structures 404 in the second direction, where a bottom portion of the trench 406 exposes the source lines SL. Dry etching is performed on the semiconductor epitaxial layer 402 and the device isolation structures 404 to form the trench 406 in the semiconductor epitaxial layer 402, for example. Through an etching selection ratio between the semiconductor epitaxial layer 402 and the device isolation structures 404, the trench 406 is allowed to have a first depth d1 between the device isolation structures 404 and a second depth d2 at a location where the trench 406 intersects the device isolation structures 404. Further, the first depth d1 is greater than the second depth d2.

Next, with reference to FIG. 4D, a tunnel oxide layer 408 is formed in the trench 406, and the floating gate FG is further formed in the trench 406, where the floating gate FG is, for example, polycrystalline silicon.

Next, with reference to FIG. 4E, an etch back may be performed to make a top portion of the floating gate FG slightly lower than a top portion of the trench 406, a portion of the tunnel oxide layer is exposed, and the exposed tunnel oxide layer is then removed. That is, the tunnel oxide layer 408 between the floating gate FG and the source line SL and between the floating gate FG and the semiconductor epitaxial layer 402 is kept.

Next, with reference to FIG. 4F, FIG. 5C, and FIG. 6C together, an inter-gate dielectric layer 410 is formed sidewalls of the trench 406 and the floating gate FG, where the inter-gate dielectric layer 410 is, for example, a high-k layer or an ONO layer. Next, the control gate CG is formed in the trench 406 on the floating gate FG, and a portion of the inter-gate dielectric layer 410 is exposed. First, a conductor material (e.g., polysilicon) filling the trench 406 is formed on the semiconductor epitaxial layer 402, the conductor material outside the trench 406 is removed through a planarization process (e.g., CMP), and a portion of the conductor material is then etched to form the control gate CG, for example, but it is not limited thereto, so that the top portion of the control gate CG is lower than the top portion of the trench 406.

After that, with reference to FIG. 5D and FIG. 6D, the dielectric layer 414 may be filled in the trench 406, and a plurality of drain regions 412 are formed in the semiconductor epitaxial layer 402 on both sides of the control gate CG. Herein, ion implantation and thermal annealing may be performed to dope the regions in the semiconductor epitaxial layer 402, so as to form the drain regions 412, for example, but it is not limited thereto.

Next, with reference to FIG. 4G and FIG. 5E together, the bit line BL extending in the first direction are formed on the semiconductor epitaxial layer 402. The bit line BL is electrically connected to the plurality of drain regions 412. In FIG. 5E, the bit line BL is preferably in direct contact with the drain regions 412. Nevertheless, the disclosure is not construed as limited thereto. In another embodiment, another inner dielectric layer (not shown) may be formed first above the semiconductor epitaxial layer 102 to cover the drain regions 112, and a conductive plug such as a via window (not shown) is then formed in the inner dielectric layer to connect the bit line BL and the drain regions 112.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A non-volatile memory device, comprising:
a substrate;
a source line formed in the substrate;
a semiconductor epitaxial layer formed on the substrate;
a device isolation structure formed in the semiconductor epitaxial layer and extending in a first direction;
a trench formed in the semiconductor epitaxial layer and crossing the device isolation structure in a second direction, wherein a bottom portion of the trench exposes the source line;
a floating gate disposed in the trench;
a tunnel oxide layer disposed between the floating gate and the source line;
a control gate disposed above the floating gate and extending in the second direction;
an inter-gate dielectric layer disposed between the floating gate and the control gate;
a plurality of drain regions formed in the semiconductor epitaxial layer on both sides of the control gate; and
a bit line extending on the semiconductor epitaxial layer in the first direction and electrically connected to the plurality of drain regions.

2. The non-volatile memory device according to claim 1, wherein the source line extends in the first direction and overlaps the bit line.

3. The non-volatile memory device according to claim 1, wherein the source line extends in the second direction and overlaps the control gate.

4. The non-volatile memory device according to claim 1, wherein a top portion of the control gate is lower than a top portion of the trench.

5. The non-volatile memory device according to claim 1, further comprising a dielectric layer between the control gate and the bit line, wherein the dielectric layer fills the trench.

6. The non-volatile memory device according to claim 1, wherein the trench has a first depth at a location where the floating gate is formed, the trench has a second depth at a location where the trench intersects the device isolation structure, and the first depth is greater than the second depth.

7. The non-volatile memory device according to claim 1, wherein the bit line is in direct contact with the plurality of drain regions.

8. The non-volatile memory device according to claim 1, wherein the tunnel oxide layer further extends between the floating gate and the semiconductor epitaxial layer.

9. The non-volatile memory device according to claim 1, wherein the inter-gate dielectric layer further extends between the control gate and the plurality of drain regions.

10. The non-volatile memory device according to claim 1, wherein the inter-gate dielectric layer comprises a high dielectric constant (high-k) layer or an ONO layer.

11. A manufacturing method of a non-volatile memory device, comprising:
forming a source line in a substrate;
forming a semiconductor epitaxial layer on the substrate;
forming a plurality of device isolation structures in the semiconductor epitaxial layer in a first direction;
forming a trench in the semiconductor epitaxial layer, wherein the trench crosses the plurality of device isolation structures in a second direction, and a bottom portion of the trench exposes the source line;
forming a tunnel oxide layer in the trench;
forming a floating gate on the bottom portion of the trench and exposing a portion of the tunnel oxide layer;
removing the exposed tunnel oxide layer;
forming an inter-gate dielectric layer on side walls of the trench and the floating gate;
forming a control gate in the trench on the floating gate and exposing a portion of the inter-gate dielectric layer;
forming a plurality of drain regions in the semiconductor epitaxial layer on both sides of the control gate; and
forming a bit line extending in the first direction on the semiconductor epitaxial layer, wherein the bit line is electrically connected to the plurality of drain regions.

12. The manufacturing method of the non-volatile memory device according to claim 11, wherein the step of forming the source line in the substrate comprises: forming the source line extending in the first direction.

13. The manufacturing method of the non-volatile memory device according to claim 11, wherein the step of forming the source line in the substrate comprises: forming the source line extending in the second direction.

14. The manufacturing method of the non-volatile memory device according to claim 11, wherein after the control gate is formed, the method further comprises: filling the trench with a dielectric layer.

15. The manufacturing method of the non-volatile memory device according to claim 11, wherein the step of forming the trench in the semiconductor epitaxial layer comprises:
performing dry etching on the semiconductor epitaxial layer and the plurality of device isolation structures, allowing the trench to have a first depth between the plurality of device isolation structures and a second depth at a location where the trench intersects the device isolation structures through an etching selection ratio between the semiconductor epitaxial layer and the plurality of device isolation structures, wherein the first depth is greater than the second depth.

16. The manufacturing method of the non-volatile memory device according to claim 11, wherein the method of forming the control gate comprises:
forming a conductor material filling the trench on the semiconductor epitaxial layer;
removing the conductor material outside the trench through a planarization process; and
etching a portion of the conductor material, so that a top portion of the control gate is lower than a top portion of the trench.

17. The manufacturing method of the non-volatile memory device according to claim 11, wherein the bit line is in direct contact with the plurality of drain regions.
